(19) United States
(12) Patent Application Publication
(10) Pub. No.: US 2023/0258711 A1
(43) Pub. Date: Aug. 17, 2023

(54) LEAK TESTING SYSTEMS AND METHODS THEREOF

(71) Applicant: SCIEMETRIC INSTRUMENTS INC., Kanata (CA)

(72) Inventors: Steven WHITE, Ottawa (CA); Richard BRINE, Ottawa (CA)

(21) Appl. No.: 18/170,702

(22) Filed: Feb. 17, 2023

Related U.S. Application Data
(60) Provisional application No. 63/268,161, filed on Feb. 17, 2022.

(51) Int. Cl. G01R 31/28

(52) U.S. Cl. CPC G01R 31/2877; G01R 31/2863

(57) ABSTRACT

The present disclosure relates to a system and method for reducing stabilization times. The system includes at least a device-under-test (DUT), a flow generator, and optionally a heat exchanger to accelerate the thermal stabilization of fluid in the DUT during and after it has been filled with test gas. This rapidly equilibrates the temperature of the fluid in the DUT to the heat exchange medium, thereby reducing temperature differentials. The reduced magnitude of the temperature differential reduces the flows associated with temperature change of the fluid due to this thermal stabilization. As a result, this allows the leak test measurement to be made in less time, or for more of the cycle time to be used for leak measurement and, thus increase the accuracy of the test measurement.

### TECHNICAL FIELD

The present disclosure relates to a leak testing system. More specifically, the present disclosure relates to a leak testing system for reducing stabilization times.

### BACKGROUND

Leak testing requires accurate measurements of very small flow rates of a gas or liquid within what may in some instances be made for a large volume. Typically, testing results are measured as a flow rate, such as standard cubic centimeters per minute (sccm) or cubic centimeters of helium per second (cc/s He) and millibar liters per second (mbar.1/s) and may, according to application, range from 10⁻³ to 10⁻¹² mbar.1/s. In some cases, the leak flow rate is correlated to a “virtual pinhole,” to quantify the size of potential defects. For example, to prevent contamination, in small volume leak testing, a sterilized medical package must be sealed such that a “virtual pinhole” in the product is smaller than the size of the smallest microorganism (commonly 0.2 μm in diameter). This theoretical pinhole dimension and the leak flow rate are correlated to each other.

Irrespective of the actual component, device, part, product and/or system being leak tested, the balance of speed, accuracy, and cost of testing exists. While increased speed (reduced time) of leak testing reduces cost per unit, this however may lead to increased costs from yield (as rejections may actually have passed with an increased accuracy test) and/or product failures and customer impact (as products failing at the customer which were incorrectly passed impact yield, customer satisfaction, and in critical cases, may lead directly to damages payable by the manufacturer). Accordingly, there is considerable benefit to manufacturers in increasing accuracy, increasing speed, and increasing defect detection in manufacturing leak testing.

Additionally, some scenarios present further issues, such as, for example, large volume leak testing. Leak testing with large part volumes in, for example, 100 L (approximately 26.4 gallons) and above range, creates additional challenges including temperature sensitivity and pressure sensitivity. For example, in an electric vehicle (EV), one challenge in manufacturing electric vehicles is ensuring the performance of large battery packs which power the vehicles. A leaking battery is more than just an inconvenience, but a safety issue. Specifically, the most common type of EV battery (e.g., lithium ion) can burst into flame or even explode if there is a leak. All components of an EV battery are vulnerable to leaks. For example, the cells, the modules, the cooling components, and the packs themselves that make up the final assembly are all susceptible. In all cases, part size, accepted leak rate, and temperature are key variables. As a first step in ensuring a reliable leak test for EV battery packs, the manufacturer must understand the impact that product design and material selection choices will have on establishing the proper test specification and test method.

There are different pneumatic leak test methods including pressure decay, mass flow and pressure or vacuum each having their own testing strengths and weaknesses as they pertain to the unique physical characteristics of a pack. These test methods are generally governed by the ideal gas law: pressure (P)×volume (V)=amount of gas in moles (n)×universal gas constant (R)×absolute temperature (T) of the gas or PV=nRT.

While the focus of pneumatic leak testing is changes in pressure and flow, changes in temperature and volume have a significant effect on the measurement. For instance, to stimulate a leak the pressure of the gas in a part (e.g., battery pack) or outside the part is changed to create a differential pressure between the inside and outside of the part. This change in pressure creates a temperature change of the gas. This temperature change needs to dissipate, and as this heat transfer occurs the pressure and flow will change independently of the leak. For some leak tests, a significant portion of time is dominated by this thermal heat transfer between the compressed fluid and the part and/or ambient environment. The duration of these thermal effects is affected by surface area and part volume, i.e., typically as the part increase in size, stabilization times get longer.

Some approaches in resolving the stabilization time are to: wait for the thermal stabilization to occur, subtract the thermal effects from the leak estimate as a fixed offset, or measure the thermal effects and compensate for the effect. However, all these approaches are time consuming and can still result in inaccurate measurement readings.

Accordingly, there remains a need to improve leak testing methods and reduce stabilization times in gas-based testing.

### SUMMARY

In an exemplary embodiment, a system and method for reducing stabilization times are provided. The system includes at least a device-under-test (DUT), a flow generator, and optionally a heat exchanger to accelerate a thermal stabilization of fluid in the DUT during and after it has been filled with test gas. The flow generator increases the rate of heat transfer. The heat exchanger rapidly equilibrates the temperature of the fluid in the DUT to the heat exchange medium, thereby reducing temperature differentials. The reduced magnitude of the temperature differential reduces the flows associated with temperature change of the fluid due to thermal stabilization. As a result, this allows the leak test measurement to be made in less time, or for more of the cycle time to be used for leak measurement and, thus increase the accuracy of the test measurement.

In a further exemplary embodiment, a system for reducing stabilization times in leak testing is provided. The system includes a circulation loop external to the device-under-test (DUT) comprising an isolation valve disposed near an inlet of the loop, a flow generator configured to circulate a fluid through the loop, a heat exchanger configured to regulate the temperature of the fluid received from the flow generator, an isolation valve disposed near the outlet of the loop, and a controller for selectively operating the isolation valves, flow generator and the heat exchanger during various stages of the leak testing.

In yet a further embodiment, a method for reducing stabilization times in leak testing comprises operating a two isolation valves to remove the circulation loop and isolate a device-under-test (DUT), operating a flow generator to ON during a fill stage and a stabilization stage, operating a heat exchanger to ON during the fill stage and the stabilization stage, and operating the flow generator and the heat exchanger to ON or OFF during a test stage and an exhaust stage. The isolation valves can optionally CLOSE remove the loop during the test stage but are OPEN during the fill, stabilize and exhaust stages.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 is a schematic representation of a portion a leak testing system, according to an example embodiment.

FIG. 2 is a schematic view of an axial flow generator, according to an example embodiment.

FIG. 3 is a schematic view of a regenerative blower flow generator, according to another example embodiment.

FIG. 4 is a chart of leak test data of FIG. 1, according to an example embodiment.

FIG. 5 is a thermal image of a flow generator and a tubing, according to an example embodiment.

FIGS. 6A and 6B are thermal images of a flow generator and a heat exchanger, according to another example embodiment.

FIGS. 7A and 7B are charts of leak test data of FIG. 1, according to an example embodiment.

FIGS. 8A and 8B are schematic representations of a leak testing system, according to other example embodiments.

FIG. 9 is a flowchart of a method of reducing stabilization time during leak testing, according to an example embodiment.

FIGS. 10A and 10B are charts of leak test data, according to an example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

The present disclosure relates to leak testing, more specifically, leak testing to significantly reduce thermal stabilization times of a gas in a device-under-test (DUT). The present disclosure demonstrates and/or provides the benefits of, such as, effect of increased flow rate on stabilization time reduction, necessity of the heat exchanger in steady state operation, ability to reduce the stabilization time to that of a single air exchange through the heat exchanger, and/or inclusion of isolation valves so as a) to eliminate any leaks from a blower loop, b) to reduce the temperature rise of the blower, and/or c) to eliminate the need for a heat exchanger.

A “device-under-test” (DUT) as used herein and throughout this disclosure, refers to an item being tested for a leak. This includes, but is not limited to, devices, parts, components, packages, packaging, containers, piping systems, individual elements, sub-systems and systems requiring that they isolate the interior from the ambient exterior. A DUT may or may not be intended to form part of a hydraulic, pneumatic, or fluidic system.

A “leak test” as used herein and throughout this disclosure, refers to processes and/or methods of determining whether a DUT has a leak which may, for example, comprise placing the DUT under a positive pressure relative to its environment and determining attributes of the pressure/flow to determine the rate of leakage from the DUT. However, leak test as used herein is not limited to positive pressure testing and may include, but not be limited to, negative pressure leak testing wherein DUTs cannot be placed under positive pressure. Such testing may be performed with a fluid including, for example, air, nitrogen, helium and other gases, as well as water, silicone oil, and other liquids.

One of the longest delays in leak testing is during a stabilization phase. In this phase, the heat that has been added to the gas through the compression of the gas inside the DUT during a fill portion of the leak test is dissipating into an inside surface of the DUT. As this air inside the DUT exchanges heat with the inside surface of the DUT, the pressure in the DUT drops in a pressure decay test (or an increased flow is measured in a flow-based test) or the pressure reaches equilibrium in a mass flow leak test. These processes can take time and are controlled by the physical characteristics of fluid and the inside surface of the DUT including volume of air, velocity of air, inside surface area, inside surface geometry, and inside surface finish.

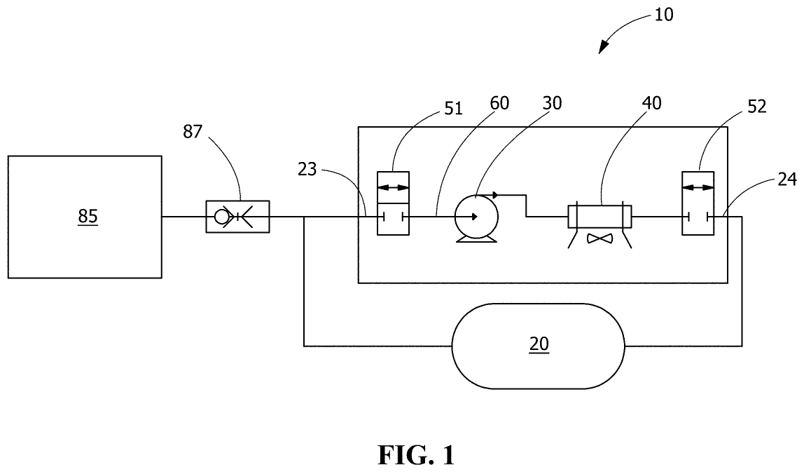

FIG. 1 is a schematic diagram of a pneumatic leak testing system 10 representing only a part to be tested and the necessary connections to the part itself. As illustrated, a leak test instrument 85 is connected to a device-under-test (DUT) 20 by a pneumatic connection 87. It should be appreciated that the schematic diagram of FIG. 1 does not include the details of the leak test instrument itself. An exemplary leak test instrument is Sentinel 3520 by Sciemetric Instruments Inc. It should further be appreciated that the actual schematic of the leak testing system can vary with the testing methodology (i.e., pressure decay, differential pressure decay, mass flow, or volume decay), and can be equally applicable to all testing types.

The system 10 includes the DUT 20 to be tested for leaks. The DUT 20 may be any part to be leak tested with typical volumes ranging from 1 L (0.264 gallons) to 1000 L (264 gallons). System 10 can also be used for leak testing under 1 L, but the severity of the fluid temperature effect increases with volume and test pressure, so there is a cost-benefit aspect to consider when applying this technology. In an example implementation, the DUT 20 is a sealed battery component for an electric vehicle (EV). More specifically, the DUT 20 can be a battery coolant loop, the battery enclosure or tray, a fully assembled battery pack, etc. In another implementation, the DUT 20 can be part of an internal combustion engine, such as, for example, an oil cavity, a fuel rail, etc.

During the fill and stabilization phases of the leak testing, the DUT 20 is filled with fluid (e.g., air) by the leak tester 85, such that the fluid inside the DUT 20 is at a different pressure than that outside the DUT 20. This pressure differential stimulates the leak which is to be measured. The work done on the fluid to change the pressure results in the fluid changing temperature relative to the DUT 20, such that heat transfer between the fluid and the DUT 20 will occur until it reaches equilibrium. When thermal equilibrium is achieved, which means the fluid inside the DUT 20 and the material comprising the DUT 20 are the same temperature, the measured leak can be obtained. If thermal equilibrium is not achieved, the measured leak is influenced by the rate of change of temperature associated with heat transfer. A correction and its associated uncertainty must be applied to compensate for the thermal stabilization, which will decrease repeatability compared to a system where the thermal stabilization is substantially more complete. For instance, while the temperature is stabilizing, the leak can be estimated by subtracting the estimated flow associated with the temperature change from the total flow into the DUT 20. It is difficult to measure the flow associated with the temperature change independently, and so this subtraction is prone to significant error.

In order to advance thermal stabilization, the system 10 includes a flow generator 30 and a heat exchanger 40 connected in series forming a circulation loop with the DUT 20. The flow generator 30 increases the velocity of the fluid and thus the rate of collisions between the fluid and the DUT 20, thereby increasing the rate of heat transfer between the DUT 20 and the fluid. In some implementations, the heat exchanger 40 is positioned after the flow generator 30 to regulate the temperature of a fluid in the DUT 20 to that of the heat exchange medium. More specifically, the heat exchanger 40 can regulate the temperature of the fluid by removing the heat produced by the flow generator 30 in addition to the heat in the fluid medium resulting from the test. Using the ambient environment as the heat exchange medium equilibrates the temperature of the fluid in the DUT 20 and the part itself to the ambient environment, thereby reducing temperature differentials. As a result, this reduces the magnitude of the thermally induced flow and reduces the need for temperature compensation strategies, improving the accuracy of the measurement.

The system 10, including the DUT 20, the flow generator 30, the heat exchanger 40, and tubing 60, is a sealed system. That is, the system 10 has a sealed path from an inlet 23 to an outlet 24 forming a loop. The inlet 23 and the outlet 24 of the loop should be designed to maximize fluid exchange with the DUT 20. Typically, this involves having the inlet 23 and the outlet 24 at different ports. In other implementations, the system 10 can include only one port. When the system 10 includes only one port, efforts should be taken to orient the inlet and outlet paths within the DUT 20 so that the loop has fluid that represents an average fluid temperature in the DUT 20.

If either the flow generator 30 or the heat exchanger 40 or any other part of the circulation loop leak, or substantially increase the test volume, it may be desirable to remove the circulation loop from the leak test during the leak measurement. In one implementation, this can be accomplished by the addition of two optional isolation valves 51 and 52 on the inlet 23 and outlet 24 of the circulation loop.

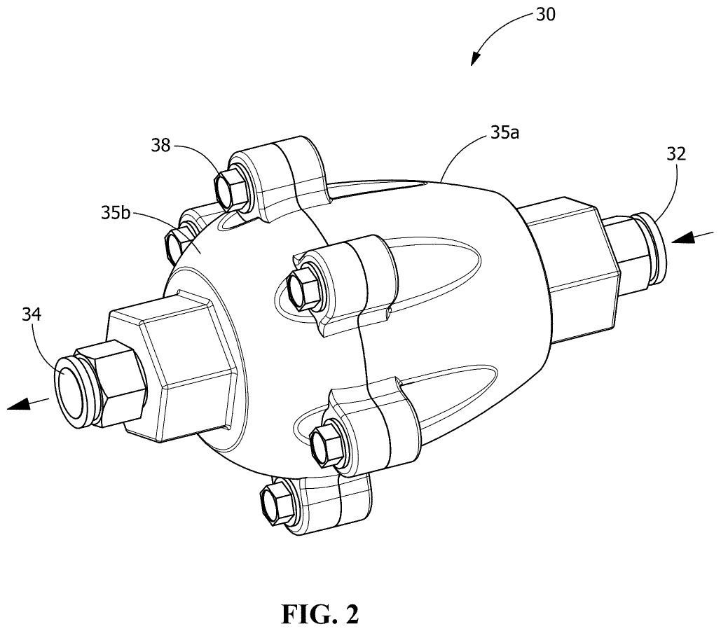

Referring to FIG. 2, the flow generator 30 mixes and circulates the fluid, while under pressure, to the heat exchanger 40. As exemplary embodiments, the flow generator 30 can be designated as a regenerative blower, a centrifugal blower, and/or any type of air pump or air compressor. As illustrated in FIG. 2, this flow generator 30 is an axial flow generator. In some implementations, the flow generator 30 includes an inlet 32 for receiving the fluid and an outlet 34 for exhausting the fluid via the tubing 60. In some implementations, the flow generator 30 can be a two-part member including a first member 35a and a second member 35b connected to each other via a plurality of fastening means 38 (e.g., bolts). In other implementations, the flow generator 30 can be a one-piece member. Inside of the flow generator 30, a propeller (not shown) can be found in a closed loop. The propellor can be a fan, a regenerative blower, a centrifugal blower, or even a piston pump. This propellor can be driven by any means that does not interfere with the seal integrity of the system, including any type of motor (electric, air, gas) sealed inside the flow generator, or outside coupled through the seal (e.g., via a magnetic drive). In an example implementation, the flow generator 30 may be sized for a 40×40×28 mm propeller and a ½ inch NPT fitting. It should be appreciated that other sizes of the propeller and/or fitting may be employed depending on the desired output and performance.

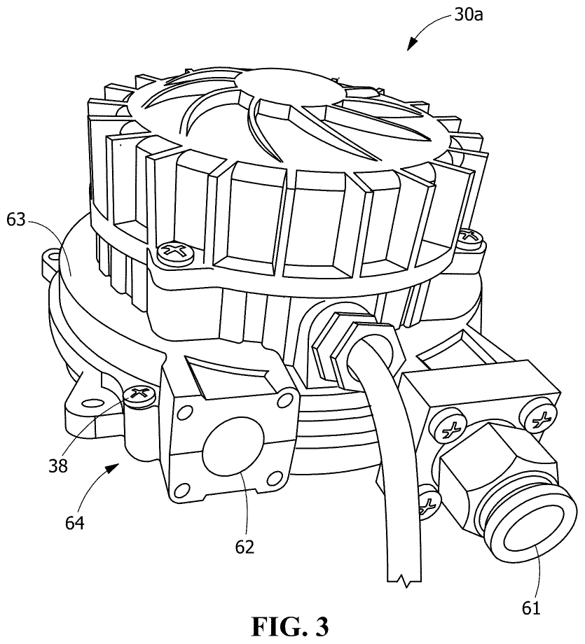

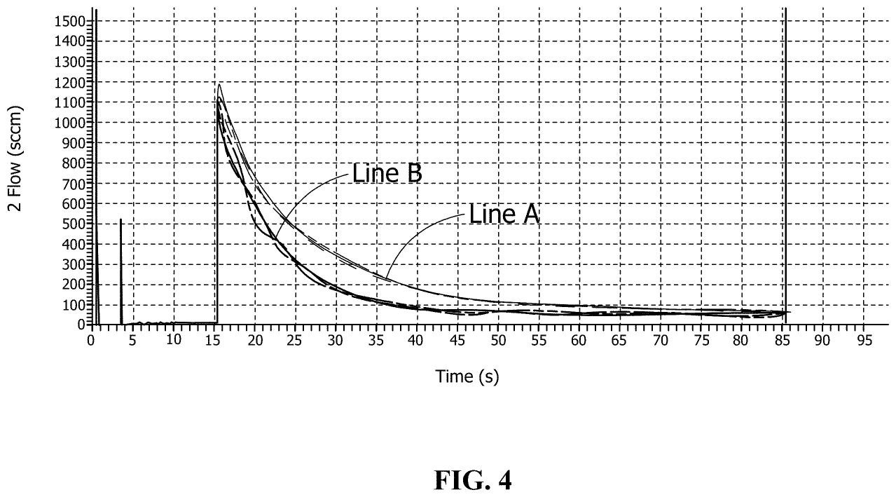

The flow generator 30 facilitates the reduction in stabilization times for thermal equilibrium by increasing the rate of heat transfer between the air and the DUT 20. For example, the graph of FIG. 4 (which measures the operation of the blower 30 of FIG. 2 and omits the isolation valves 51, 52 and the heat exchanger 40) illustrates a comparison of the flow generator 30 at ON and OFF. As shown in the graph, line A depicts the flow generator 30 in an OFF position, and line B depicts the flow generator 30 in an ON position. When the flow generator 30 is OFF, the thermal stabilization does not occur until at approximately at 67 sec; however, when the flow generator 30 is ON, the thermal stabilization occurs approximately at 42 sec, which is relatively faster when compared to the flow generator 30 is OFF. Hence, utilizing the flow generator 30 shows faster heat transfer and a reduction in thermal stabilization times.

FIG. 3 illustrates a flow generator 30a in accordance with another exemplary embodiment. In the implementation shown, the flow generator 30a of FIG. 3 is a regenerative blower powered by an electric motor. The flow generator 30a includes an inlet port 61 for receiving fluid from the DUT 20, and an outlet port 62 that can connect to the heat exchanger 40 and back to the DUT 20. It is critical that the flow generator be sealed to withstand the test pressure. In this example the blower casing and cable port must be sealed by means such as O-rings and RTV. In one implementation, the flow generator 30a as described herein is configured for a final leak rate of about 47 sccm at 5 psig.

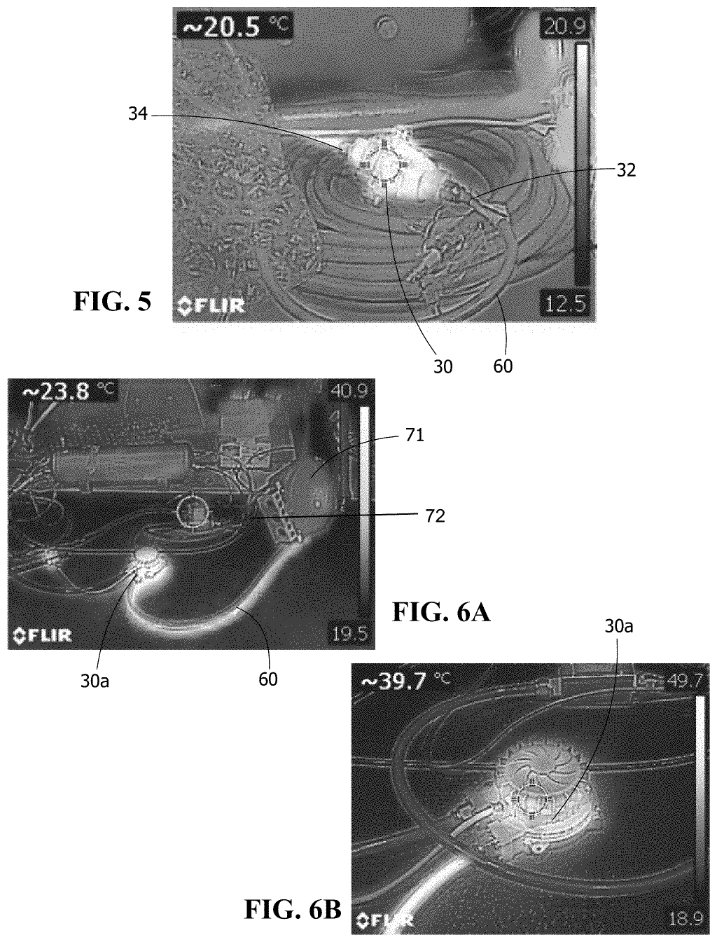

When powered, the flow generator 30 or 30a produces heat due to losses and the work it is doing to accelerate the fluid medium. If significant to the leak test this heat is undesirable and should be removed. In some implementations, a heat exchanger 40 is positioned after the flow generator 30 or 30a to regulate the temperature of the fluid by removing the heat produced by the flow generator 30 or 30a in addition to the heat in the fluid medium resulting from the test. For illustration, as shown in FIG. 5, which is a thermal image of the flow generator 30 of FIG. 2 connected to the tubing 60, the fluid in the inlet side 32 of the flow generator 30 has a first temperature and the fluid in the outlet side 34 of the flow generator 30 has a second temperature, which is higher than the first temperature. In one implementation, the fluid temperature of the inlet side 32 of the flow generator 30 is approximately 17° C. and the fluid temperature at the outlet side 34 of the flow generator 30 is approximately 21° C. In this scenario, the ambient temperature was approximately 20.5° C. and the tubing 60 between the flow generator 30 and the DUT 20 acted as a heat exchanger via conduction through the tube walls for exposure to the surrounding atmosphere, so no additional equipment was required. In these cases, the longer the tubing 60 the greater the heat removal.

In other implementations, FIGS. 6A and 6B illustrate thermal images of the blower 30a of FIG. 3 connected to a heat exchanger 71. FIG. 6B demonstrates that the inlet port of the blower 30a receives the fluid from the DUT 20 at approximately 20° C. and the outlet port measures 49.7° C. A spot temperature measurement of the blower casing reads 39.7° C. As shown in FIG. 6A, the heat exchanger 71 is properly operating with the inlet tubing 60 measuring −40° C. and the outlet tubing 72 measuring −20° C., effectively removing heat introduced by the blower 30a. The present disclosure demonstrates that the heat exchanger 40 should be located after the flow generator 30, so as to remove heat produced by the flow generator 30 and the heated fluid from the test, resulting in reduced temperature differentials in the system.

Referring to TABLE 1, there is shown resulting stabilization times when operating the flow generator shown in FIG. 3 (i.e., blower 30a) and heat exchanger configuration in FIG. 6 with a 9.5 L DUT tested at 5 psig. Increasing the blower flow rate from 0 sLpm (line E) to 84 sLpm (line A) achieved an 84% stabilization time improvement from 81 sec to 13 sec.

TABLE 1

| | | Heat | | | Time for | | Stabilization |
|---|---|---|---|---|---|---|---|
| | Blower | exchanger | | Air | flow | Stabilization | time |
| Test | Control | fan | Blower flow | exchanges/ | <50 sccm | time | reduction |
| Runs | (V) | (V) | (sLpm @ 5 psig) | minute | (s) | (s) | (%) |
| A | 10 | 10 | 84 | 6.7 | 18 | 13 | 84% |
| B | 5 | 10 | 61 | 4.8 | 21 | 16 | 80% |
| C | 2 | 10 | 18 | 1.4 | 35 | 30 | 62% |
| D | 1 | 10 | 6 | 0.5 | 58 | 54 | 33% |
| E | 0 | 0 | 0 | 0 | 87 | 81 | 0% |

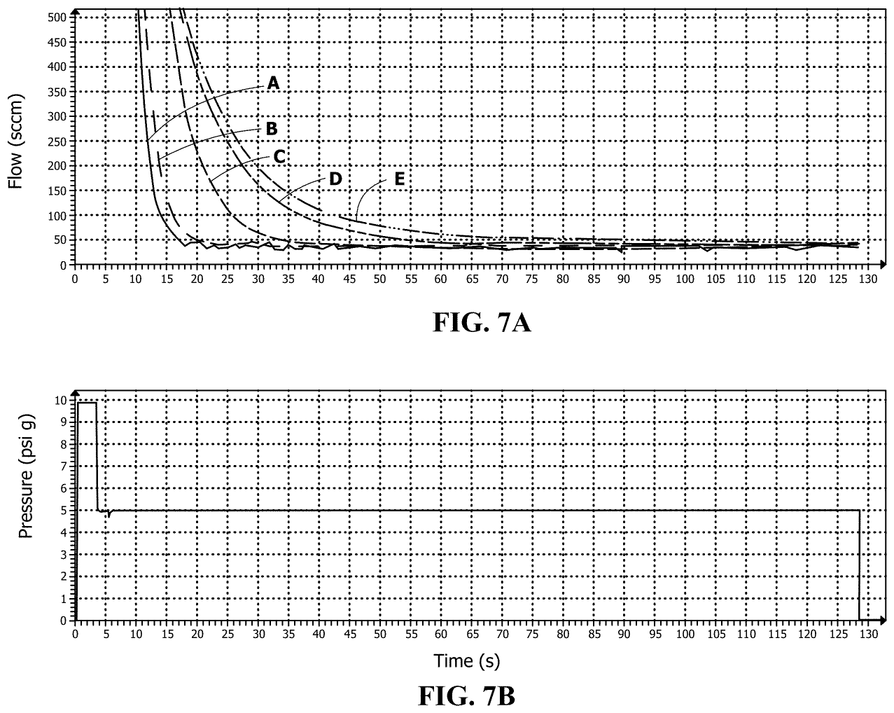

As depicted in FIG. 7A, the chart demonstrates that when the flow generator (indicated as line E) is not operating, the stabilization time of gas in the DUT 20 is 81 sec. When the flow generator (indicated as line D) is at 6 sLpm flow rate, the thermal stabilization time of gas in the DUT 20 is 54 sec, which is a 33% reduction. When the flow generator (indicated as line C) is at 18 sLpm flow rate, the thermal stabilization time of gas in the DUT 20 is 30 sec, which is a 62% reduction. When the flow generator (indicated as line B) is at 61 sLpm flow rate, the thermal stabilization time of gas in the DUT 20 is 16 sec, which is a 80% reduction. When the flow generator (indicated as line A) is at 84 sLpm flow rate, the thermal stabilization time of gas in the DUT 20 is 13 sec, which is a 84% reduction. Further, the charts are normalized to the final leak to better differentiate stabilization characteristics, i.e., demonstrate that sizing the flow generator to the part produces the predicted results. That is, the stabilization time can be reduced to that of a single air exchange through the heat exchanger. As a result, a 9.5 L tank at 5 psig has 12.9 sL of air therein. With the flow generator having 87 sLpm, the air can be stabilized in <10 s, whereas for comparison, in natural convection, the same tank requires 40-50 s to stabilize. As such, the thermal stabilization time is drastically reduced. FIG. 7B shows the pressure profile at the leak tester. A fast fill pressure of 10 psig was used to rapidly fill the part to 5 psig in approximately 3 sec. The 5 psig test pressure was then held steady for the duration of the flow test.

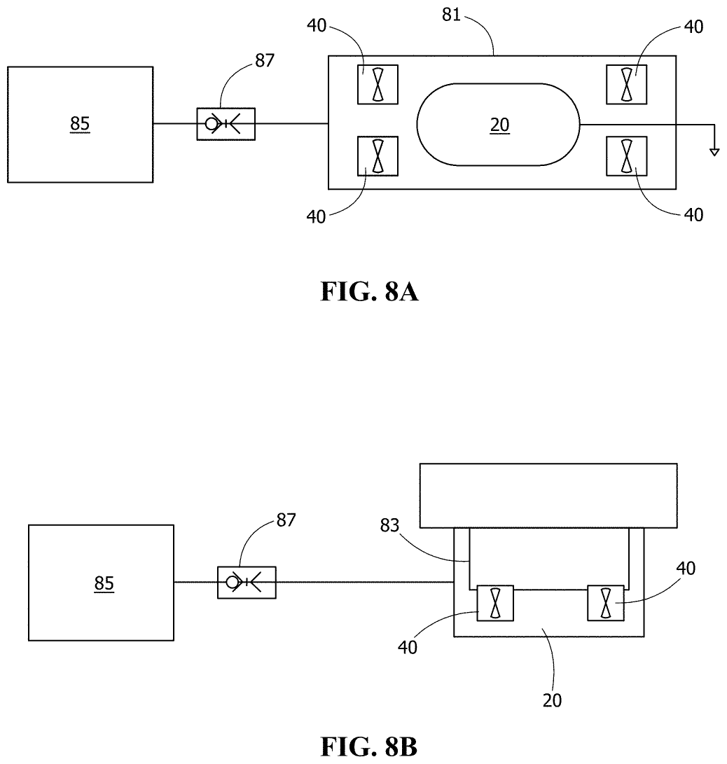

It should be appreciated that the schematic diagram shown in FIG. 1 is only one typology for leak testing, that can be described as an “egress” test whereby fluid inside the part is pressurized and leaks out. This environment can typically be used for battery coolant loop testing, for example. Other configurations can be employed for a leak testing system in accordance to various embodiments. For example, as shown in FIG. 8A, a sealed test enclosure 81 surrounds or encloses the part 20. Pressurizing the test enclosure 81 and porting the DUT 20 to ambient conditions constitutes an “ingress” test, whereby the leak test instrument 85 is connected via 87 to the enclosure and it is the enclosure 87 leak into the DUT 20 that is measured. In this implementation, only one port on the DUT is required and one or more flow generators (i.e., blowers or fans) 40 inside of the enclosure 81 circulate the fluid there inside. The flow generators 40 act to improve heat transfer between the air and the DUT 20. It should be appreciated that the flow generators 40 will always consume power and therefore add heat to the system. If the flow generators 40 are on for a short enough time, the heat added to the system may be negligible, thus eliminating the need for a heat exchanger. If however, too much heat is added an external heat exchange loop (not shown) can also be added.

In alternative “egress” testing, as shown in FIG. 8B, for parts with large internal cavities that require plugging, the fans 40 can be installed directly to a fixture 83 installed inside of the part 20. In this case the fixture 83 both reduces the test volume and improves heat transfer by active circulation. A portion of the fixture 83 is installed outside of the part 20. This configuration is suited for battery tray testing, for example.

In some implementations, other devices may be employed to further enhance the accuracy of the leak testing. For example, a pressure regulator can be used to keep the fluid pressure at a desired test pressure and/or a flow sensor to measure the flow of fluid to the DUT and/or to other devices. In some implementations, a filter may be coupled to the source to filter the fluid. The filter may also be coupled near the pressure regulator.

In some implementations, control methods can be used to minimize the heat generated by the flow generator, and thereby reduce the need for an active heat exchange. Leak testing is typically broken down into fill, stabilize, test, and exhaust test stages. During the fill and stabilize test stages, the flow generator and heat exchanger should be ON. During all other test and exhaust stages, the flow generator and heat exchanger can be turned OFF to reduce any noise the flow generator and/or heat exchanger introduce into the measurement through turbulence. This approach also saves power and reduces the heat generated by the active devices.

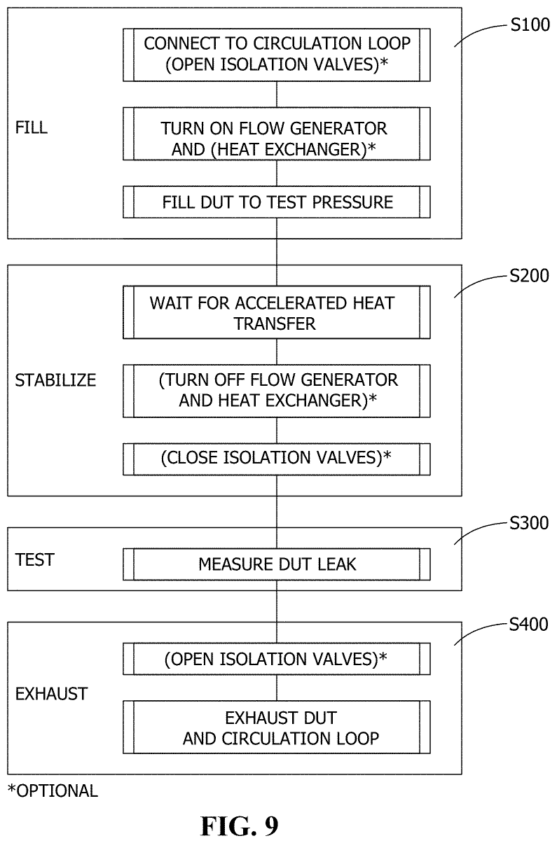

FIG. 9 is a flowchart of a method of reducing stabilization time during leak testing of a DUT according to an example embodiment. In step S100, during the fill stage, the system connects the DUT to the circulation loop. If the optional isolation valves are implemented, the isolation valves must be open during this stage. The flow generator and the heat exchanger are turned ON, and the DUT and circulation loop are pressurized to the test pressure. In step S200, during the stabilization stage, the flow generator and optionally heat exchanger operate to accelerate heat transfer. When this heat transfer is complete, the flow generator and optionally heat exchanger may be optionally turned off, and the isolation valves may be optionally closed to remove the circulation loop and any of its associated leaks from the test volume. Thus, the flow generator and optionally heat exchanger are ON to mix and circulate the fluid during the substantial majority of the fill and stabilization test stages. In step S300, during the test stage, the leak of the DUT is measured. If the circulation loop is not isolated then the measured leak includes that of the circulation loop, and the optional heat exchanger and flow generator may be left ON to continue to hold temperature in equilibrium. In step S400, during the exhaust stage, the circulation loop should be re-connected to the DUT and then both the DUT and the circulation loop shall be exhausted.

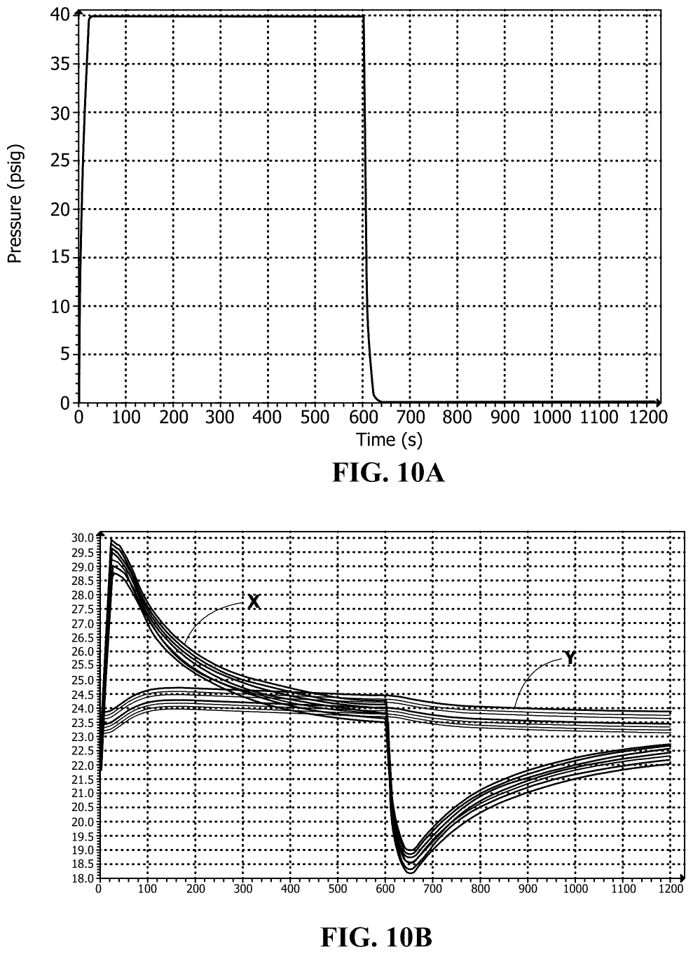

FIGS. 10A and 10B show the thermal cycle of a typical part. FIG. 10A illustrate the pressure waveform where the part is filled to 40 psig for 600 sec and exhausted for 600 sec. FIG. 10B illustrate multiple records of the air temperature (as indicated by “X”), and the part temperature (as indicated by “Y”). During pressurization, the air temperature increases, and begins to transfer heat to the part. This causes the part temperature to rise above ambient and begin heat exchange with the ambient environment. When the air in the part is exhausted the air cools and the part temperature starts to fall. As such, the exemplary embodiments as described herein can achieve this same result which is to accelerate this heat transfer process.

Implementation of the techniques, blocks, steps and means described above may be done in various ways. For example, these techniques, blocks, steps and means may be implemented in some instances as electronic circuits which may comprise hardware, software, or a combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described above and/or a combination thereof.

Also, it is noted that the embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process is terminated when its operations are completed, but could have additional steps not included in the figure. A process may correspond to a method, a function, a procedure, a subroutine, a subprogram, etc. When a process corresponds to a function, its termination corresponds to a return of the function to the calling function or the main function.

Furthermore, embodiments may be implemented by hardware, software, scripting languages, firmware, middleware, microcode, hardware description languages and/or any combination thereof. When implemented in software, firmware, middleware, scripting language and/or microcode, the program code or code segments to perform the necessary tasks may be stored in a machine readable medium, such as a storage medium. A code segment or machine-executable instruction may represent a procedure, a function, a subprogram, a program, a routine, a subroutine, a module, a software package, a script, a class, or any combination of instructions, data structures and/or program statements. A code segment may be coupled to another code segment or a hardware circuit by passing and/or receiving information, data, arguments, parameters and/or memory contents. Information, arguments, parameters, data, etc. may be passed, forwarded, or transmitted via any suitable means including memory sharing, message passing, token passing, network transmission, etc.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory. Memory may be implemented within the processor or external to the processor and may vary in implementation where the memory is employed in storing software codes for subsequent execution to that when the memory is employed in executing the software codes. As used herein the term “memory” refers to any type of long term, short term, volatile, nonvolatile, or other storage medium and is not to be limited to any particular type of memory or number of memories, or type of media upon which memory is stored.

Moreover, as disclosed herein, the term “storage medium” may represent one or more devices for storing data, including read only memory (ROM), random access memory (RAM), magnetic RAM, core memory, magnetic disk storage mediums, optical storage mediums, flash memory devices and/or other machine readable mediums for storing information. The term “machine-readable medium” includes, but is not limited to portable or fixed storage devices, optical storage devices, wireless channels and/or various other mediums capable of storing, containing or carrying instruction(s) and/or data.

The methodologies described herein are, in one or more embodiments, performable by a machine which includes one or more processors that accept code segments containing instructions. For any of the methods described herein, when the instructions are executed by the machine, the machine performs the method. Any machine capable of executing a set of instructions (sequential or otherwise) that specify actions to be taken by that machine are included. Thus, a typical machine may be exemplified by a typical processing system that includes one or more processors. Each processor may include one or more of a CPU, a graphics-processing unit, and a programmable DSP unit. The processing system further may include a memory subsystem including main RAM and/or a static RAM, and/or ROM. A bus subsystem may be included for communicating between the components. If the processing system requires a display, such a display may be included, e.g., a liquid crystal display (LCD). If manual data entry is required, the processing system also includes an input device such as one or more of an alphanumeric input unit such as a keyboard, a pointing control device such as a mouse, and so forth.

The memory includes machine-readable code segments (e.g. software or software code) including instructions for performing, when executed by the processing system, one of more of the methods described herein. The software may reside entirely in the memory, or may also reside, completely or at least partially, within the RAM and/or within the processor during execution thereof by the computer system. Thus, the memory and the processor also constitute a system comprising machine-readable code.

In alternative embodiments, the machine operates as a standalone device or may be connected, e.g., networked to other machines, in a networked deployment, the machine may operate in the capacity of a server or a client machine in server-client network environment, or as a peer machine in a peer-to-peer or distributed network environment. The machine may be, for example, a computer, a server, a cluster of servers, a cluster of computers, a web appliance, a distributed computing environment, a cloud computing environment, or any machine capable of executing a set of instructions (sequential or otherwise) that specify actions to be taken by that machine. The term “machine” may also be taken to include any collection of machines that individually or jointly execute a set (or multiple sets) of instructions to perform any one or more of the methodologies discussed herein.

The aspects and embodiments of the invention can be used alone or in combinations with each other.

The articles “a” and “an,” as used herein, mean one or more when applied to any feature in embodiments of the present disclosure described in the specification and claims. The use of “a” and “an” does not limit the meaning to a single feature unless such a limit is specifically stated. The article “the” preceding singular or plural nouns or noun phrases denotes a particular specified feature or particular specified features and may have a singular or plural connotation depending upon the context in which it is used. The adjective “any” means one, some, or all indiscriminately of whatever quantity.

“At least one,” as used herein, means one or more and thus includes individual components as well as mixtures/combinations.

The transitional terms “comprising”, “consisting essentially of” and “consisting of”, when used in the appended claims, in original and amended form, define the claim scope with respect to what unrecited additional claim elements or steps, if any, are excluded from the scope of the claim(s). The term “comprising” is intended to be inclusive or open-ended and does not exclude any additional, unrecited element, method, step or material. The term “consisting of” excludes any element, step or material other than those specified in the claim and, in the latter instance, impurities ordinarily associated with the specified material(s). The term “consisting essentially of” limits the scope of a claim to the specified elements, steps or material(s) and those that do not materially affect the basic and novel characteristic(s) of the claimed disclosure. All materials and methods described herein that embody the present disclosure can, in alternate embodiments, be more specifically defined by any of the transitional terms “comprising,” “consisting essentially of,” and “consisting of.”

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While the disclosure has been described with reference to a preferred embodiment, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

What is claimed is:

1. A system for leak testing a device-in-test (DUT), comprising:
a flow generator configured to circulate a fluid in the system,
wherein the circulated fluid produced by the flow generator causes reduction of thermal stabilization time and acceleration of thermal stabilization of gas in the DUT.

2. The system according to claim 1, further comprising a heat exchanger, wherein the heat exchanger is located in series with the flow generator and configured to further transfer heat between the fluid and ambient environment so as to reduce temperature differential between the DUT and the ambient environment.

3. The system according to claim 2, wherein the heat exchanger is located after the flow generator in a fluid circuit to regulate the temperature of the fluid in the DUT.

4. The system according to claim 2, wherein the heat exchanger transfers heat produced by the flow generator.

5. The system according to claim 4, wherein the heat exchanger transfers heat between the fluid and the ambient environment resulting from the testing.

6. The system according to claim 2, wherein the flow generator and the heat exchanger are located outside of the DUT.

7. The system according to claim 2, wherein the flow generator is located inside of the DUT.

8. The system according to claim 1, wherein heat is removed from the system via conduction through walls of the tube for exposure to a surrounding atmosphere.

9. The system according to claim 1, wherein the flow generator is at least one of a fan, a blower, an air motor, or a pump.

10. The system according to claim 1, wherein the DUT is configured for a large volume leak testing, the large volume is greater than 1 L.

11. The system according to claim 1, wherein the DUT is for a battery leak testing for electric vehicle (EV).

12. A system for reducing stabilization times in leak testing, comprising:
a circulation loop external to the DUT;
an isolation valve disposed near an inlet of the circulation loop;
a flow generator configured to circulate a fluid in a tubing;
a heat exchanger configured to transfer heat between the fluid received from the flow generator and ambient environment;
an isolation valve disposed near an outlet of the circulation loop; and
a controller for selectively operating the flow generator, heat exchanger and isolation valves during stages of the leak testing.

13. The system according to claim 12, wherein the system is a sealed system.

14. The system according to claim 12, wherein the system includes a sealed path from the inlet to the outlet forming a loop.

15. The system according to claim 12, wherein the controller operates the isolation valves to selectively connect the circulation loop to the DUT during the leak test.

16. The system according to claim 1, further comprising multiple flow generators, wherein the multiple flow generators are located inside the DUT to further reduce thermal stabilization time.

17. The system according to claim 12, wherein the flow generator is at least one of a regenerative blower, a centrifugal blower, or any type of air pump or air compressor.

18. A method for reducing stabilization times in leak testing, comprising:
during a fill stage and a stabilization stage, operating a flow generator to ON to pressurize the DUT and the circulation loop to a test pressure;
during the fill stage and the stabilization stage, optionally operating a heat exchanger to ON to accelerate heat transfer; and
during a test stage and an exhaust stage, operating the flow generator and the heat exchanger to ON or OFF.

19. The method according to claim 18, further comprising operating isolation valves to remove the circulation loop during the test stage.

20. The method according to claim 18, wherein during the fill and the stabilization stages, the flow generator operates to mix and circulate a fluid.

21. The method according to claim 18, wherein during the fill and the stabilization stages, the heat exchanger operates to remove heat produced by the flow generator.

22. The method according to claim 18, wherein during the fill and the stabilization stages, the heat exchanger removes heat in the fluid.
